(19) United States
(12) Patent Application Publication
(10) Pub. No.: US 2009/0097004 A1
(43) Pub. Date: Apr. 16, 2009

(54) Lithography Apparatus, Masks for Non-Telecentric Exposure and Methods of Manufacturing Integrated Circuits

(75) Inventors: Sven Trogisch, Dresden (DE); Christoph Hohle, Moritzburg (DE); Wolf-Dieter Domke, Adelsdorf (DE); Gunther Ruhl, Kumhausen (DE)

Correspondence Address: EDELL, SHAPIRO & FINNAN, LLC, 1901 RESEARCH BLVD., SUITE 400, ROCKVILLE, MD, 20850, US

(73) Assignees: QIMONDA AG, Munich (DE); INFINEON TECHNOLOGIES AG, Neubiberg (DE)

(21) Appl. No.: 11/873,128

(22) Filed: Oct. 16, 2007

(51) Int. Cl. G03B 27/54; G03F 1/00

(52) U.S. Cl. 355/67; 430/5

(57) ABSTRACT

A lithography apparatus includes a first optical system configured to irradiate a mask with a non-telecentric illumination and a second optical system configured to guide radiation reflected off or transmitted through the mask to a substrate. The mask includes an absorber structure arranged over a non-absorbing surface, wherein the absorber structure includes sidewalls extending in a first direction intersecting a main plane of incidence of the non-telecentric illumination. The sidewall angle of the sidewalls may be at most equal to 90° minus the angle of incidence of the non-telecentric illumination and at least equal to 90° minus the sum of the angle of incidence and a half acceptance angle of the second optical system.

### BACKGROUND

Extreme ultraviolet lithography (EUV) uses reflective photomasks with an oblique illumination angle, resulting in imaging characteristics that differ from those of conventional optical lithography. For example, the topography of an absorber pattern on top of a reflective mask may cause shadow effects for absorber lines that run perpendicular to the plane of incidence resulting in structure displacement and alterations of lateral dimensions of the imaged structures. Optical proximity correction techniques may be implemented to adapt the absorber structures on the mask to compensate shadow effects to a certain degree. Shadow effects may also occur with conventional, transmissive optical lithography.

Further, during manufacturing of an integrated circuit, a plurality of exposure processes are necessary, wherein patterns resulting from different exposure processes must be adjusted to each other. The patterns to be imaged are provided such that they show a tolerance against a maximum admissible misalignment of the lithographic exposures. The greater the inherent imaging aberrations, for example, resulting from non-telecentric illumination, are, the greater this tolerance must be on costs of substrate space and yield.

Therefore a need exists for a lithography apparatus and a method of manufacturing integrated circuits which may reduce the required overlay tolerances.

### SUMMARY

Described herein is a lithography apparatus comprising a first optical system configured to irradiate a mask with a non-telecentric illumination and a second optical system configured to guide radiation reflected off or transmitted through the mask to a substrate. The mask comprises an absorber structure arranged over a non-absorbing surface, wherein the absorber structure includes sidewalls extending in a first direction intersecting a main plane of incidence of the non-telecentric illumination. The sidewall angle of the sidewalls may be at most equal to 90° minus the angle of incidence of the non-telecentric illumination and at least equal to 90° minus the sum of the angle of incidence and a half acceptance angle of the second optical system.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Features and advantages of exemplary embodiments will be apparent from the following description of the drawings. The drawings are not to scale. Emphasis is placed upon illustrating the principles.

FIG. 1A is a schematic perspective illustration of a non-telecentric illumination of a mask.

FIG. 1B is a schematic plan view of a section of the mask of FIG. 1A comprising absorber lines perpendicular to the main plane of incidence.

FIG. 1C is a schematic cross-sectional view of the section of the mask of FIG. 1B.

FIG. 1D is a schematic plan view of a section of the mask of FIG. 1A comprising absorber lines running parallel to a main plane of incidence.

FIG. 1E is a schematic cross-sectional view of the section of the mask of FIG. 1D.

FIG. 1F is a diagram illustrating the effect of non-telecentric illumination of the mask of FIG. 1A.

FIG. 1G is an aerial image illustrating the effect of non-telecentric illumination in dependence on defocus.

FIG. 1H is a diagram illustrating another example for a non-telecentric illumination effect underlying exemplary embodiments.

FIG. 2 is a schematic illustration of a non-telecentric illumination of a reflective mask according to an exemplary embodiment.

FIG. 3A is a diagram plotting the pattern shift over defocus.

FIG. 3B is a further diagram plotting the pattern shift over defocus as a function of the sidewall angle for illustrating a principle of the exemplary embodiments.

FIG. 4 is a schematic illustration of a reflective lithography apparatus for non-telecentric illumination according to an another exemplary embodiment.

FIG. 5A a schematic cross-sectional view of a section of a mask comprising a 3D-pattern with symmetric sidewalls according to an exemplary embodiment.

FIG. 5B a schematic cross-sectional view of a section of a mask comprising a 3D-pattern with symmetric sidewalls according to another exemplary embodiment.

FIG. 5C a schematic cross-sectional view of a section of a mask comprising a 3D-pattern with asymmetric sidewalls according to a further embodiment.

FIG. 6 is a flow chart of a method of manufacturing photomasks according to a further embodiment.

FIG. 7 is a flow chart of a method of manufacturing integrated circuits according to a further embodiment.

### DETAILED DESCRIPTION

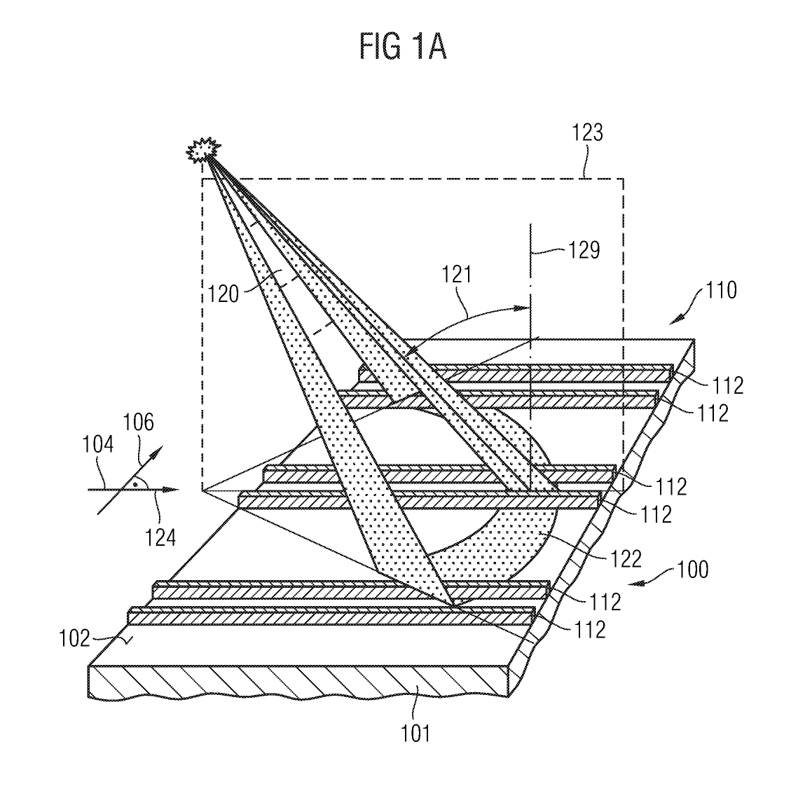

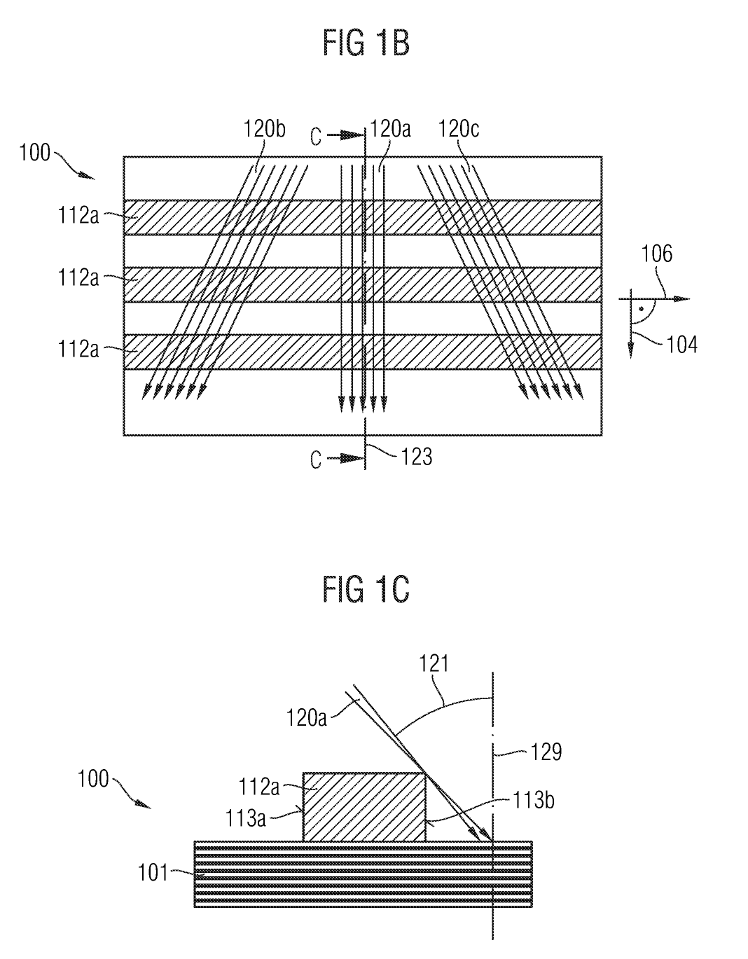

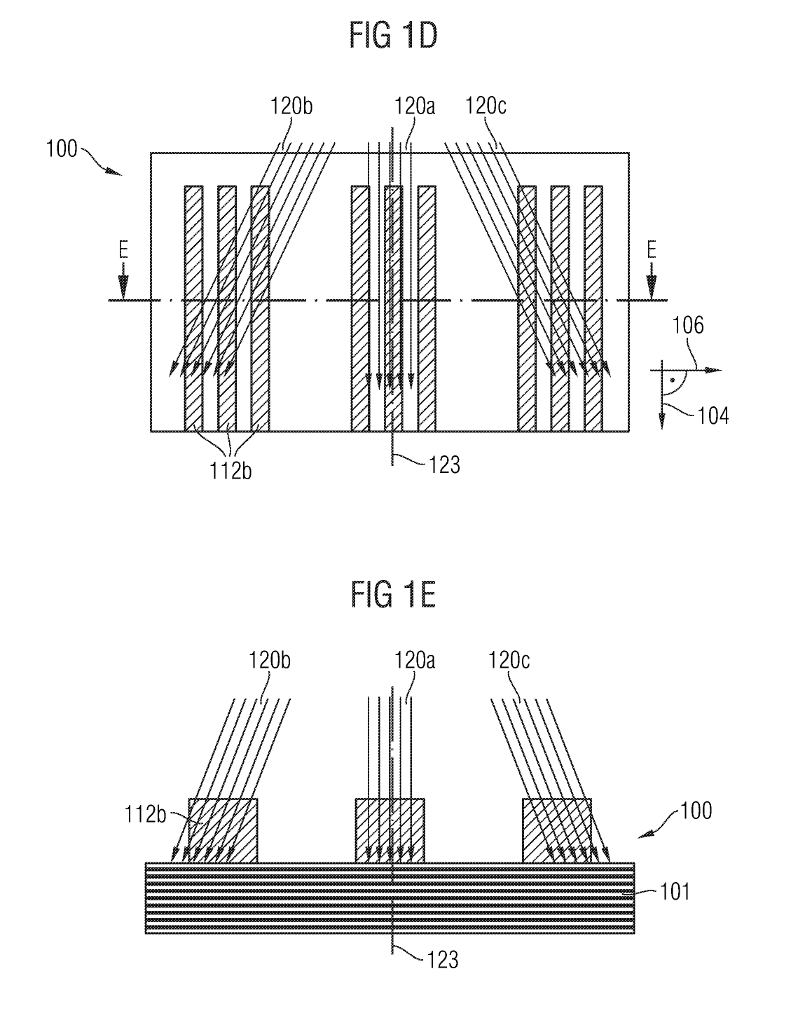

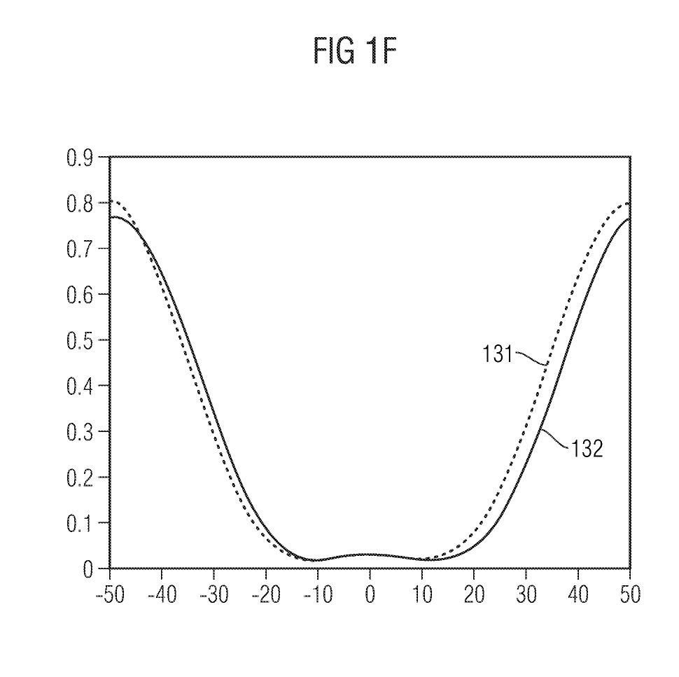

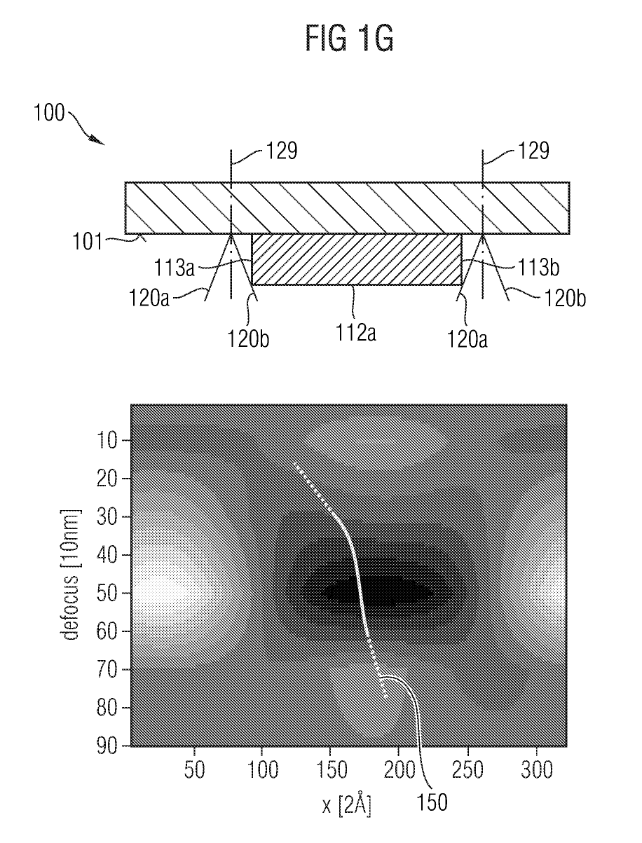

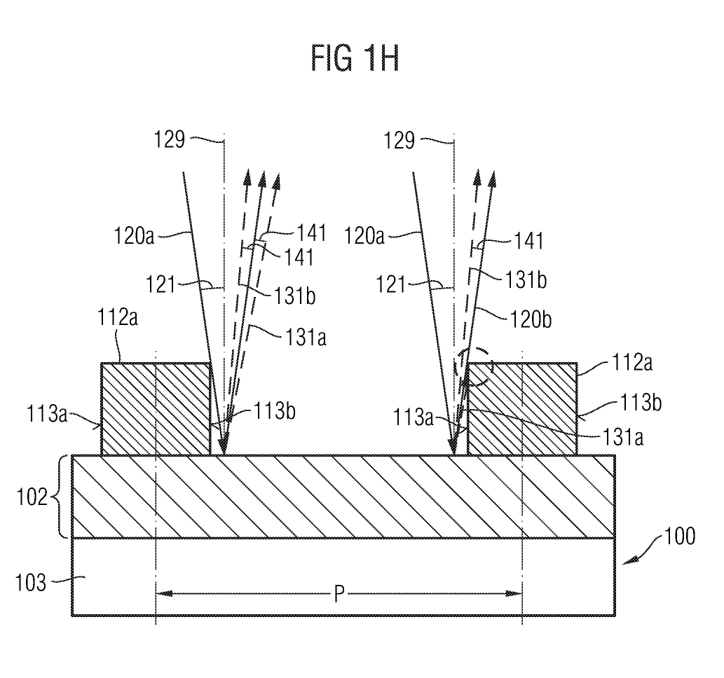

FIGS. 1A to 1H refer to simplified illustrations of an incident illumination beam 120 irradiating a mask or reticle 100 for illustrating effects of non-telecentric illumination.

The mask 100 illustrated in FIG. 1A comprises an absorber pattern 110 arranged on a non-absorbing surface 102 of a substrate 101. The absorber pattern 110 comprises absorber structures 112 which may be oval, elliptic or circular dots or dots of, for example, rectangular shape with or without rounded corners. The absorber structures 112 may also be lines which may comprise straight sections extending along a first axis 104 or a second axis 106 which is perpendicular to the first axis 104. The absorber structures 112 may also comprise slanted sections running oblique to the first and second axes 104, 106. At an illumination wavelength of, for example, 13.5 nm, 193 nm, 248 nm or any other wavelength used for mask illumination, the absorber pattern 110 has an absorbance that is significantly greater than that of the non-absorbing surface 102 at the same wavelength.

The substrate 101 is either transparent or to a high degree reflective at the illumination wavelength. An illumination beam 120 irradiates the mask 100 with a radiation at the illumination wavelength. The radiation from, for example, an EUV source, is collected and shaped to the illumination beam 120, which illuminates an image field that may be, by way of example, a narrow arc or an annular segment (ring field) 122. The width of the image field is selected sufficiently narrow to achieve sufficient contrast on one hand and sufficiently wide to get enough radiation for exposing, by way of example, a resist on a target substrate, into which the absorber pattern 110 is imaged and transferred. The width may be in the range of up to several millimeters. The length of the image field may be selected, for example, such that it extends over at least the minimum dimension (length or width) of a pattern region of the mask 100, such that the pattern may be screened or scanned in one contiguous scan. A typical width or length of the mask 100 is in the range of 80 to 150 mm. The mean radius of the ring field is limited by technical restrictions of the condenser optics of the lithography apparatus. Within this restriction the mean radius is selected as large as possible. The illumination beam 120 may be symmetric with respect to a main plane of incidence 123 which is orthogonal to the non-absorbing surface 102 and which extends along, for example, the first axis 104. The illumination is non-telecentric, meaning that, in the main plane of incidence 123, the illumination beam 120 has a mean incident angle 121 which is not equal zero with respect to the normal 129 but is about four to ten degree, for example, six or nine degrees. By way of example, the illumination beam 120 may scan the mask 100 parallel to the first axis 104 (e.g., along a first direction 124) which faces away from the incident illumination beam 120 on the first axis 104.

The mask 100 may be mounted on a mask stage that moves the mask 100 during an illumination period (e.g., reverse to the first direction 124) such that a scan direction, along which the illumination beam 120 scans the mask 100, corresponds to the first direction 124.

According to an exemplary embodiment, the illumination beam 120 is EUV radiation of a wavelength of 13.5 nanometers. The absorber structures 112 may be tantalum nitride based and the substrate 101 may include a multi-layer reflector comprising, for example, 20 to 60 molybdenum and silicon layers in alternating order. In accordance to further embodiments, the mask 100 may further comprise a capping layer (e.g., a ruthenium layer) arranged on top of the multi-layer reflector.

According to another embodiment, the illumination radiation 120 is a DUV (deep ultraviolet) radiation of, for example, 193 nanometer wavelength, the absorber structures 112 are, for example, chromium structures, and the substrate 101 may be a doped silicon oxide (e.g., a titanium doped silicon dioxide).

FIG. 1B is a schematic plan view of a section of the mask 100 comprising line-shaped absorber structures 112a running perpendicular to the first axis 104, wherein a first portion 120a of the illumination beam impinges in the main plane of incidence 123 and other portions 120b, 120c tilted to the main plane of incidence 123.

As illustrated in FIG. 1C, which is a cross-sectional view of the section of the mask 100 illustrated in FIG. 1B, the absorber structures 112a running perpendicular to the first axis 104 shadow the incident illumination radiation at their trailing sidewalls 113b, which face away from the incident illumination beam 120. In addition, in case of a reflective substrate 101, the absorber structures 112a shadow a portion of a reflected illumination radiation on their leading sidewalls 113a which face the incident radiation 120a. Further, the effective angle of incidence varies over the image field, wherein the variation is symmetric to the main plane of incidence 123. As a result, in the reflected or transmitted radiation, a feature on the mask appears wider than it actually is and the feature appears to be shifted in a direction determined by the incident angle, the height of the absorber pattern and the distance of the respective object point to the main plane of incidence 123.

FIG. 1D is another schematic plan view of another section of the mask 100 comprising line-shaped absorber structures 112b running parallel to the first axis 104, wherein a first portion 120a of the illumination beam 120 impinges in the main plane of incidence 123. Further portions 120b, 120c of the illumination beam impinge tilted to the main plane of incidence 123.

As illustrated in FIG. 1E, which is a cross-sectional view of the section of the mask 100 as illustrated in FIG. 1D, with the absorber structures 112b running parallel to the first axis 104 a shadowing effect as discussed above occurs, wherein the effect is symmetric with respect to the main plane of incidence 123. The same considerations as presented in the following with respect to the shadowing effect illustrated in FIG. 1C may therefore apply likewise to the shadowing effect as illustrated in FIG. 1E.

The diagram of FIG. 1F shows the effect of the non-telecentric illumination of absorber lines 112a, 112b as depicted in FIGS. 1B and 1D on corresponding target lines printed on a target substrate. The dotted curve 131 plots the illumination intensity assigned to one focus plane as a function of a distance to a center of the target line in the case of a non-telecentric illumination, corresponding to an absorber line 112b running parallel to the main plane of incidence, while the continuous curve 132 refers to an absorber line 112a running perpendicular to the main plane of incidence. A printed line resulting from the “perpendicular” absorber line 112a is wider and is shifted in a direction determined by the orientation of the mean incident angle 121.

The diagram in the lower part of FIG. 1G refers to a planar cross-section of an aerial image generated through a lithography apparatus of a section of a mask 100, the cross-section of which is illustrated in the upper part of FIG. 1G, wherein the cross-section is that of an absorber line 112a arranged over a non-absorbing surface 101 of the mask 100. The aerial image plots the intensity of a reflected radiation 120b as a function of locus on the abscissa and on defocus on the ordinate. The dark area in the center corresponds to a section with low intensity radiation and the bright areas to sections with high intensity radiation. The dotted line 150 refers to the barycenter of the illumination and corresponds to the resulting pattern shift or pattern displacement. The diagram illustrates the defocus dependence.

FIG. 1H refers to a further aspect of non-telecentric illumination underlying the exemplary embodiments. Though explained in detail with respect to a reflective mask in the following, essentially equivalent considerations apply to transparent masks as well.

At an absorber pattern disposed above the multi-layer reflector 102 bearing on a carrier substrate 103 of a reflective mask 100, diffraction occurs. The absorber pattern as illustrated in FIG. 1H may comprise, for example, a regular line pattern including parallel absorber lines 112a arranged at a feature pitch p of, for example, between 15 and 100 nanometers (e.g., 64 nanometers). The regular line pattern is effective as a regular reflective grating diffracting the incident illumination beam. In the diffracted wavefront constructive interference results in intensity maxima at certain angles of diffraction which depend on the feature pitch p.

On the left hand side of FIG. 1H, an incident light beam 120a impinges at an angle of incidence 121 of, for example 4 to 6 degrees next to a trailing edge 113b of the left absorber line 112a on the surface of a multi-layer reflector 102 of a mask 100. The reflected wavefront comprises the reflected radiation 120b (zero order diffraction) and diffracted radiation contributing to, for example, first diffraction orders 131a, 131b, wherein the respective diffraction angle 141 depends on the feature pitch p. The diffracted radiation contributes to both plus and minus first diffraction orders 131a, 131b.

On the right hand side of FIG. 1H, another portion of the incident light beam 120a impinges at the angle of incidence 121 next to a leading edge 113a of the right absorber line 112a on the surface of the mask 100. The absolute distance between the impinging light beam portion 120a and the absorber line 112a is the same as on the left hand side of the figure. The reflected wavefront, however, contributes only to the reflected radiation 120b (zero order diffraction) and the minus diffraction orders. The plus first diffraction order 131a and the higher plus diffraction orders are shadowed by the leading sidewall of the absorber lines 112a. As the first diffraction orders contribute to a not negligible degree to the image of the absorber lines 112a, this effect contributes to a displacement of the absorber lines 112a on a target substrate.

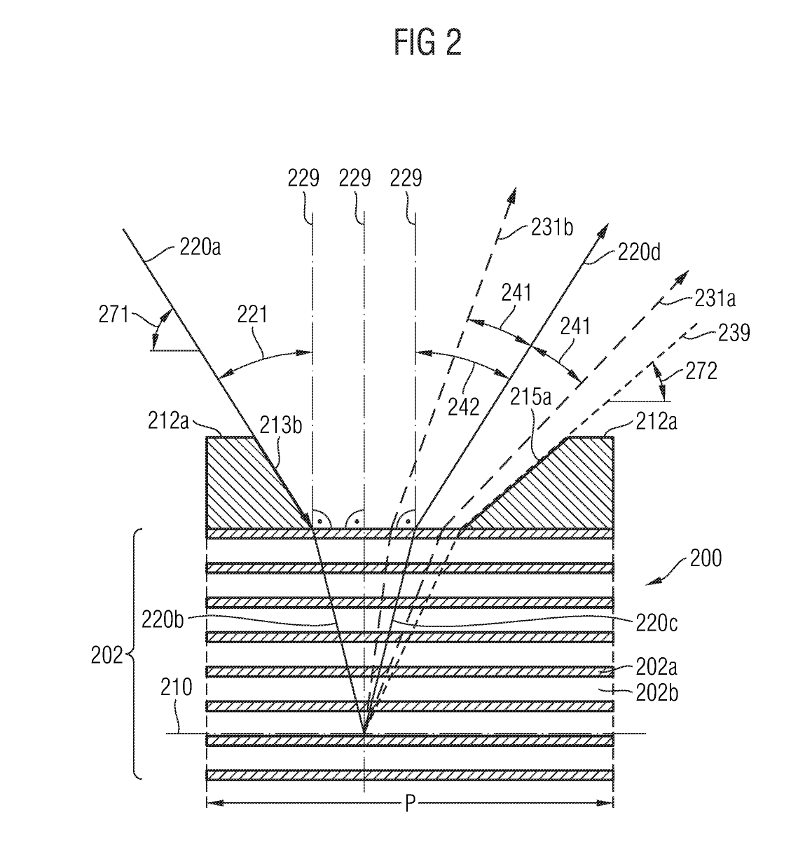

FIG. 2 shows a section of a mask 200 according to an exemplary embodiment. The mask 200 may be a transparent one or a reflective one comprising a multilayer reflector 202 which includes layers of different indices of refraction and/or different coefficients of absorption, for example first layers 202a having a first index of refraction and second layers 202b having a second index of refraction, in alternating order. In accordance to further embodiments (not shown), a capping layer may be disposed on top of the multi-layer reflector 202. Radiation entering the multilayer reflector 202 is reflected at each interface between a first layer 202a and a second layer 202b. The distance between the interfaces may be such that radiation reflected at the interfaces superposes in-phase. Due to this superposition, the plurality of reflections may be assumed as one reflection occurring on a virtual reflection plane 210.

Further, diffraction occurs at the reflective grating formed by an absorber pattern which includes, for example, a regular line pattern including parallel absorber lines 212a arranged at a feature pitch p of, for example, between 15 and 100 nanometers (e.g., 64 nanometers). Further by approximation, the point of diffraction may be assumed in the virtual reflection plane 210. The absorber lines 212a may comprise a layer of high absorbance at the illumination wavelength (e.g., a tantalum nitride based layer). An antireflective coating may be provided on top of the high absorbance layer, wherein the antireflective coating is low reflective at an inspection wavelength (e.g., 193 to more than 450 nm). The high absorbance layer may bear on a buffer layer (e.g., a silicon dioxide or chromium layer), according to further embodiments.

An incident illumination beam 220a impinges on the multi-layer reflector 202 at an incident angle 221 off normal 229. As the refractive index of the multi-layer reflector differs from that of air or vacuum, the incident illumination beam 220a is refracted on the surface of the multi-layer reflector 202. The illumination beam 220a may be refracted towards the normal 229 as illustrated. In case of EUV illumination at a wavelength of 13.5 nm, for example, the refractive index of the multi-layer reflector 202 may be such that the incident illumination beam 220a is refracted away from the normal 229. The refracted incident illumination beam 220b appears to be reflected at the virtual reflection plane 210 and the reflected refracted illumination beam 220c is refracted towards or away from the normal 229 at the surface 202 and spreads from the mask 200 as reflected illumination beam 220d.

The absorber pattern may comprise, inter alia, absorber lines 212a with trailing sidewalls 213b that face away from the incident radiation 220a and that are tilted against the mask surface at a trailing angle 271, and with leading sidewalls 215a that face the incident radiation 220a and that are tilted against the mask surface at a leading angle 272.

As diffraction occurs, the reflected illumination beam 220d spreads out in the plane of incidence which is parallel to the cross-sectional plane. By way of example, in the case of parallel absorber lines 212a arranged at the feature pitch p, a regular diffraction pattern with first 231a, 231b and higher diffraction orders occurs in the reflected wavefront, wherein the angle of diffraction 241 of equivalent orders of diffraction depends on the feature pitch of the absorber lines 212a. In the case of absorber lines extending parallel to the main plane of incidence 123, the diffraction orders spread exclusively in a plane perpendicular to the main plane of incidence 123 and symmetrically thereto.

According to an exemplary embodiment, the leading angle 272 of the absorber lines is selected in dependence on the feature pitch p such that none of both first diffraction orders 231a, 231b in the wavefront spreading from the mask is shadowed by the absorber lines 212a. According to an exemplary embodiment, a maximum leading angle may be equal to 90° minus arcsin (wavelength/p) minus incident angle.

According to another exemplary embodiment, the leading angle 272 of all absorber structures is between a minimum leading angle and a maximum leading angle, wherein the minimum leading angle is equal to the maximum leading angle decreased by one or two degrees. In another example, the leading angle is between the maximum leading angle and a minimum leading angle given by the half acceptance angle of a projection system that images the reflected radiation on a sample.

The trailing angle 271 may be equal to the leading angle. According to another embodiment, the trailing angle 271 may be at most equal to 90° minus the angle of incidence 221, as a steeper sidewall may provide an increased contrast.

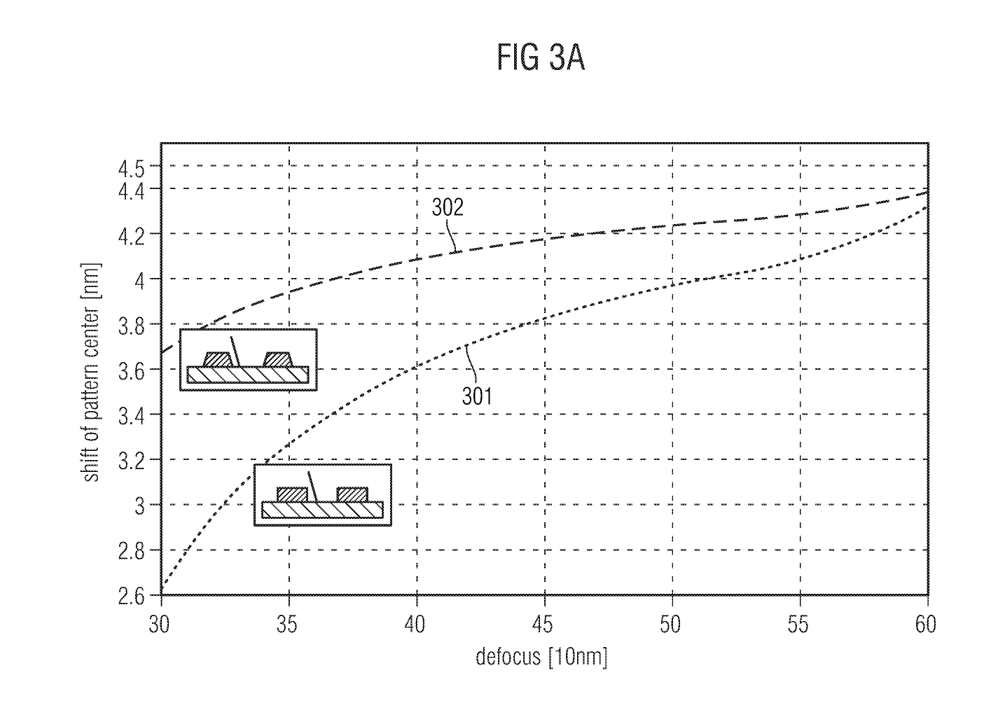

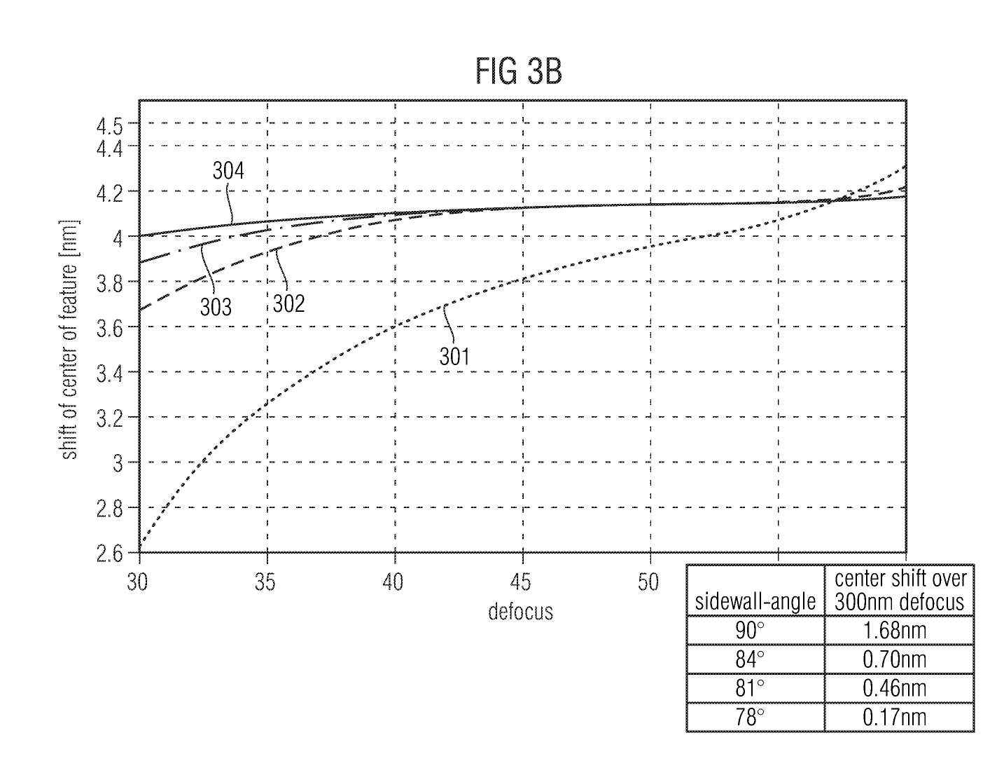

FIG. 3A illustrates the dependence of the shift of a pattern center, for example, of an absorber line, on defocus and on the sidewall angle of the absorber lines. Both curves refer to a regular absorber pattern with parallel absorber lines 112a with a line width of 32 nm and arranged at a pitch of 64 nm. The absorber pattern is illuminated at an angle of incidence of 6°. The dotted lines refer to absorber lines having perpendicular sidewalls, i.e., a sidewall angle of 90°. The continuous line 302 refers to symmetric absorber lines 112a with a sidewall angle of 84° at both the leading edge 113a and the trailing edge 113b. With the trailing edge adapted to the angle of incidence, the defocus dependence of pattern displacement may be reduced from about 1.8 nm to 0.8 nm in a defocus range of 300 nm.

FIG. 3B refers to a refractive mask with a regular absorber line pattern, wherein the absorber lines are arranged at a pitch of 64 nm and have a line width of 32 nm. The angle of incidence of the exposure illumination is 6°. All curves 301, 302, 303 and 304 refer to symmetric absorber lines having the same sidewall angle on the leading and the trailing edge. Curve 301 refers to absorber lines having a sidewall angle of 90°; curve 302 refers to absorber lines having a sidewall of 84°; curve 303 refers to absorber lines having a sidewall angle of 81°; and the continuous line 304 refers to absorber lines having a sidewall angle of 78°. The center shift of the absorber lines over a defocus of 300 nm is 1.68 nm, at a sidewall angle of 90°, 0.7 nm at a sidewall angle of 84°, 0.45 nm at a sidewall angle of 81° and 0.17 nm at a sidewall angle of 78°. Decreasing the sidewall angle from 84° to 81° halves the pattern shift of a defocus range of 300 nm. This shows that selecting the sidewall angle such that the first diffraction orders are not shadowed at the leading edge of the absorber lines reduces the defocus dependence of the pattern shift drastically. The loss in contrast between a sidewall angle of 84° and 81° is less than 1% at a defocus of −50 nm, whereas the contrast at zero defocus is slightly improved. Further, as the light of both first diffraction orders receives the substrate, more radiation reaches the substrate. Thereby, a process window for the exposure processes is improved resulting further in improved yield and/or improved device performance.

Typical absorber patterns are based upon tantalum nitride. Depending on the process conditions and the process ambient (e.g., temperature, pressure and gas supply), a chloride based etch process may supply different sidewall angles between 78° and 84°. For example, chloride may be supplied at a gas flow of about 10 to about 500 sccm at a pressure between about 2 and about 25 mTorr. The plasma may have a bias power of 20 to 300 W and a source power of 50 to 1000 W. In this ambient, the sidewall angle of titanium nitride based absorber lines depends substantially linearly on the pressure, wherein at a pressure of 3 mTorr a sidewall angle of 82.5° and at a pressure of 11 mTorr a sidewall angle of about 78.5° may be achieved. Asymmetric sidewall angles may be provided by, for example, masking the steeper sidewalls after or before a first etch step, such that a second etch step is effective only on either the leading or the trailing sidewalls. According to other embodiments, the mask may be tilted versus a sputter axis during at least a sub-period of the etch process.

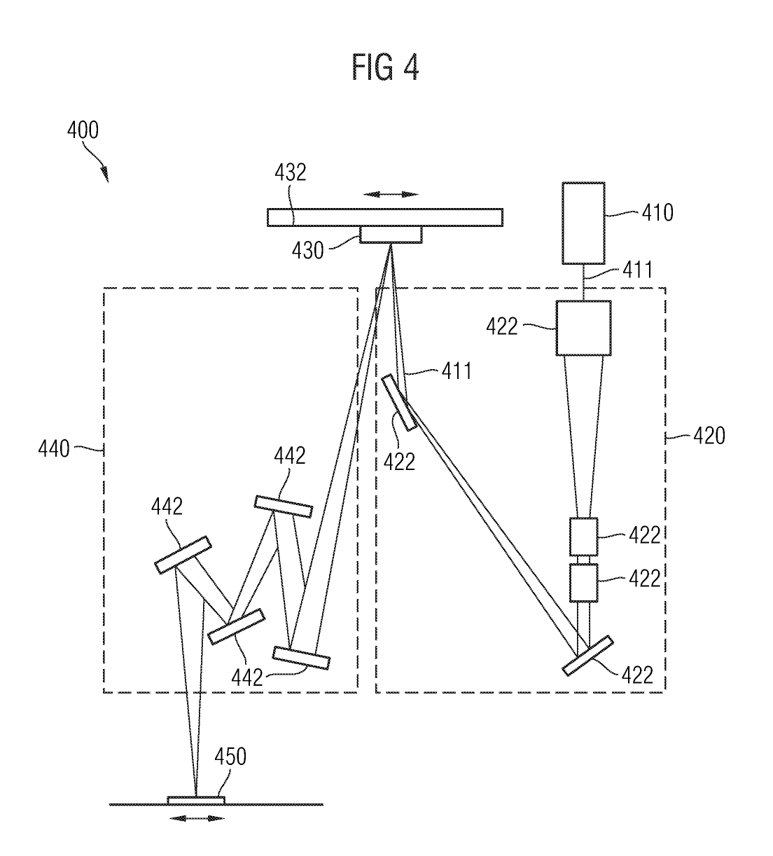

FIG. 4 is a schematic illustration of a lithography apparatus 400 with reflective elements according to an embodiment. The lithography apparatus 400 comprises a radiation source 410 which may be any source capable of producing radiation used for reflection lithography, for example an EUV source.

A condenser system 420 guides radiation 411 emitted from the radiation source 410 to a mask 430 which may be mounted on a mask stage 432. The condenser system 420 includes condenser optics 422 (e.g., mirrors), which are reflective at the radiation wavelength and which collect and focus the radiation 411 onto the mask 430. The condenser system 420 may include a plurality of condenser optics 422 (e.g., five), as shown in FIG. 4. The radiation 411 impinges on the mask 430 as illumination beam, a typical shape of which is illustrated in FIG. 1A. The mask stage 432 moves the mask 430 during an illumination period along a scan direction. The illumination beam may scan the mask 430 completely with one continuous, unidirectional scan.

The projection system 440 images the pattern on the mask 430 onto a sample 450, which is typically a semiconductor wafer in course of manufacturing integrated circuits and which is coated with a resist layer which is sensitive to radiation at the illumination wavelength. The projection system 440 includes reflective projection optics 442 (e.g., mirrors) that project radiation reflected off the mask 430 onto the sample 450 true to scale or scaled down.

According to an embodiment, the mask comprises absorber structures, wherein at least the trailing sidewalls of the absorber structures have a sidewall angle adapted to the numerical aperture of the projection system 440 and/or the angle of incidence of the condenser system 420, wherein, for example, the trailing angle is at most equal to 90° minus the angle of incidence.

According to another embodiment, the sidewall angle is at least equal to 90° minus the angle of incidence minus the half acceptance angle of the projection system 440. According to another embodiment, the sidewall angle of the trailing sidewalls is equal to 90° minus the angle of incidence. According to yet a further embodiment, the angle on the trailing sidewall is equal to 90° minus the angle of incidence and the angle on the leading sidewall is determined such that a first diffraction order of a regular line pattern is not shadowed.

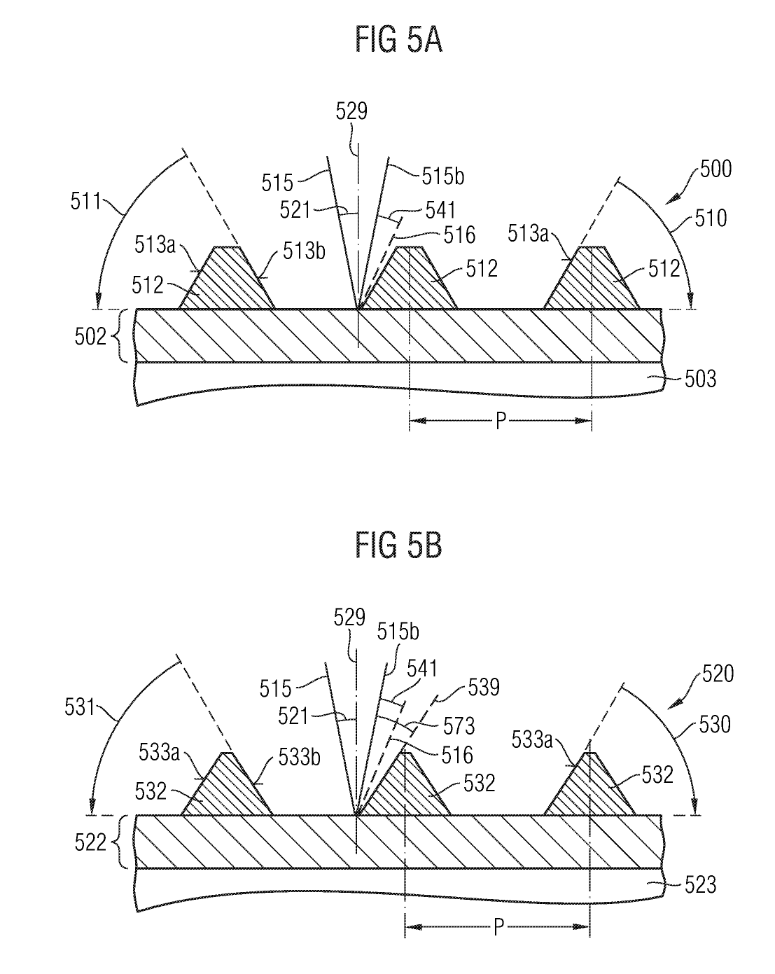

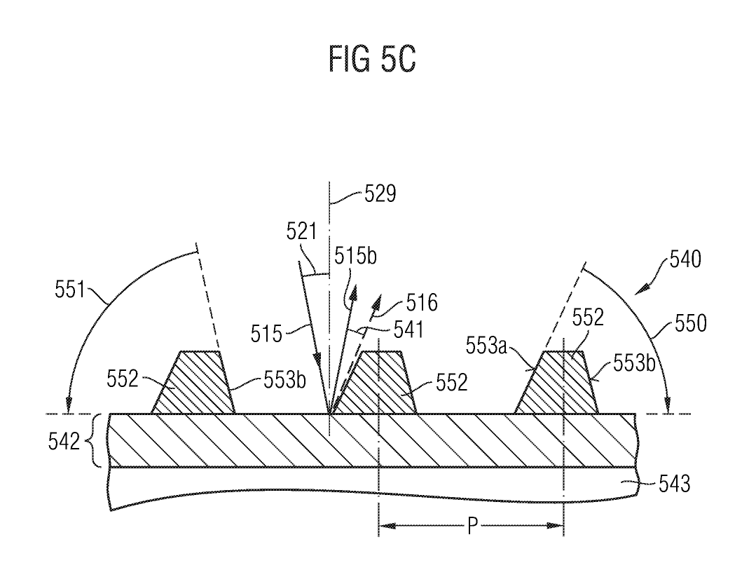

FIGS. 5A to 5C refer to photomasks according to exemplary embodiments. Each photomask 500, 520, 540 may comprise a multilayer reflector 502, 522, 542 bearing on a carrier substrate 503, 523, 543, respectively. Absorber patterns 512, 532, 552 disposed on the respective multilayer reflector 502, 522, 542 are arranged at a feature pitch p and have a significantly higher absorbance at an illumination length of, for example, 13.5 nm, 193 nm, 248 nm, 257 nm or any other wavelength used for mask illumination than the multilayer reflectors 502, 522, 542. An incident illumination beam 515 impinges at an angle of incidence 521 off normal 529, respectively. The reflected radiation 515b corresponds to the zero order diffraction, respectively, and is reflected in the main plane of incidence. The plus first diffraction order 516 is tilted at a first diffraction angle 541 off the reflected illumination beam 515b.

The mask 500 according to FIG. 5A comprises absorber line structures 512 running perpendicular to the main plane of incidence, wherein the leading sidewall angle 510 of the leading sidewalls 513a, which face the incident illumination beam 515, is selected such that the plus 516 and minus first diffraction orders may spread symmetrically from the surface of the mask 502 at the base points of the leading sidewalls 513a. According to another embodiment, the leading sidewall angle 510 is equal to 90° minus arcsin(wavelength/p) minus incident angle 521, wherein p is the feature pitch of a regular line pattern on the mask 500, such that the plus first diffraction order 516 is not absorbed and both first diffraction orders spread symmetrically. Typically, p refers to the pitch of the densest absorber lines in the absorber pattern of the mask 500. The trailing sidewall 513b may have a trailing sidewall angle 511 of 90°. According to the illustrated embodiment, the trailing sidewall angle 511 is equal to the leading sidewall angle 510. According to yet another embodiment, the trailing sidewall angle 511 is equal to the angle of incidence 521 of the condenser system of the lithography apparatus configured to be used with the mask.

The mask 520 according to FIG. 5B refers to an embodiment comprising absorber lines 532 with a leading sidewall angle 530 adapted to a lithography apparatus in which the mask 520 is mounted to pattern a semiconductor wafer in course of the fabrication of integrated circuits. The leading sidewall angle 530 of leading sidewalls 533a is adapted to the angle of incidence 521 and the acceptance angle 573 of the projection system of the lithography apparatus. The trailing sidewall angle 531 of the trailing sidewall 533b may be equal to 90° minus the angle of incidence 521 or equal to the leading sidewall angle 530.

The mask 540 according to FIG. 5C comprises asymmetric absorber lines 552 running perpendicular to the main plane of incidence. The trailing sidewall angle 551 of the trailing sidewalls 553b is equal to 90° minus the angle of incidence 521 and the leading sidewall angle 550 on the leading sidewall 553a is greater than 90° minus the angle of incidence 521 minus the half acceptance angle and less than 90° minus the angle of incidence 521 minus the diffraction angle 541 of the plus first diffraction order 516, for instance, 90° minus arcsin(wavelength/p) minus incident angle, wherein p is the feature pitch of a regular line pattern on the mask 540, such that the plus first diffraction order 516 is not absorbed. Typically, p refers to the pitch of the densest absorber lines in the absorber pattern of the mask 540.

A sidewall angle of absorber lines running parallel to the main plane of incidence may be selected according to equivalent considerations. In accordance with further embodiments, the sidewall angles depend on their orientation towards the main plane of incidence. The absorber structures may comprise an absorber layer showing a high absorbance at the illumination wavelength, an antireflective layer, which shows low reflectivity at the wavelength of an optical inspection apparatus scanning the mask pattern for defects, and buffer layers supporting a selective etch of the absorber stack with respect to the multi-layer mirror.

Each configuration of absorber lines as discussed with regard to FIG. 5A-5C may be applied to transmissive masks as well. Transmissive masks comprise typically a transparent carrier substrate which is transparent at the illumination wavelength. On one of the main sides of the carrier substrate, opaque structures form the mask pattern, wherein the opaque structures are non-transparent at the illumination wavelength. The opaque structures may be based on chromium, by way of example. According to other examples, a phase shift layer may be provided between the opaque mask pattern and the carrier substrate.

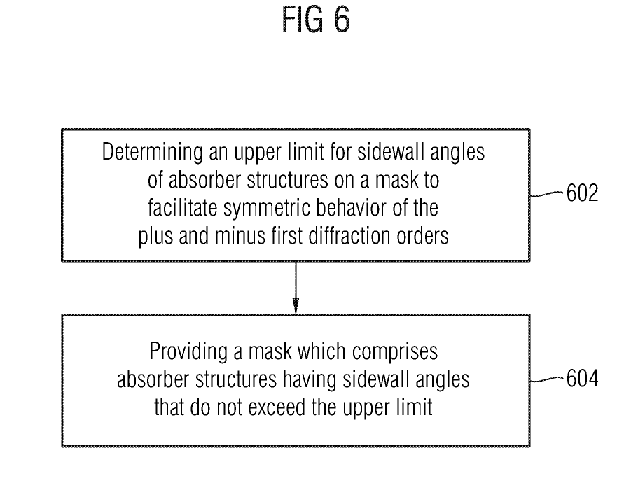

FIG. 6 shows a simplified flowchart of a method of manufacturing a mask according to another embodiment. An upper limit for sidewall angles of absorber structures that extend on a mask in a first direction intersecting a main plane of incidence of a non-telecentric illumination is selected to facilitate symmetric behavior of the plus and minus first diffraction orders (602). According to an embodiment, the upper limit is determined from an angle of incidence of the condenser optics of a lithography apparatus configured to irradiate a mask with non-telecentric illumination and from an acceptance angle of a projection system of the lithography apparatus. Then, a mask is provided which comprises absorber structures having a sidewall angle that do not exceed the upper limit (604). In case of a reflective mask, symmetrical behavior of the plus and minus first diffraction orders may be achieved, if both plus and minus first diffraction orders are reflected up to the base points of the absorber structures. In case of a transparent mask, symmetrical behavior of the plus and minus first diffraction orders may be achieved, if neither the plus nor the minus first diffraction orders impinging at the base points of the absorber structures and next to the absorber structures is absorbed.

In accordance to an embodiment of manufacturing a mask, an upper limit for a sidewall angle of absorber structures that extend in a first direction intersecting a main plane of incidence of a non-telecentric illumination is determined from an angle of incidence of a condenser optics of a lithography apparatus configured to irradiate a mask with non-telecentric illumination and from an acceptance angle of a projection system of the lithography apparatus. The upper limit is selected such that plus and minus first diffraction orders are treated symmetrically. Then, a mask with absorber structures having a sidewall angle not exceeding the upper limit is provided.

The upper limit for a sidewall angle of leading sidewalls facing the non-telecentric illumination may be equal to 90 degree minus the sum of angle of incidence and the half acceptance angle of the projection system. The upper limit for a sidewall angle of trailing sidewalls facing away from the non-telecentric illumination may be equal to 90 degree minus the angle of incidence.

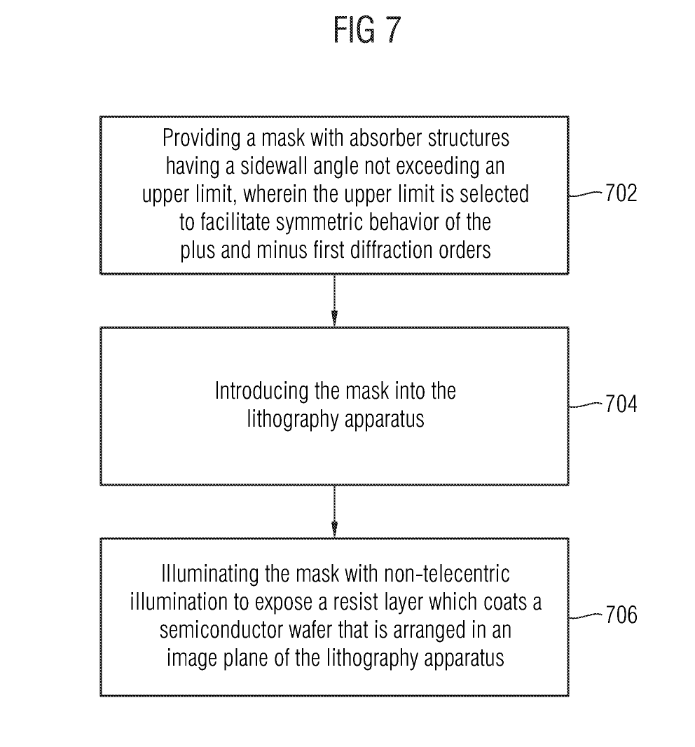

FIG. 7 is a simplified flowchart of a method of fabricating integrated circuits according to yet another embodiment. A mask is provided (702) as yet described with reference to FIG. 6. The mask is introduced into the lithography apparatus (704). Then, the mask is illuminated with non-telecentric illumination to expose a resist layer which coats a semiconductor wafer that is arranged in an image plane of the lithography apparatus, wherein from the semiconductor wafer the integrated circuits are provided (706). The semiconductor wafer may be a preprocessed silicon wafer, a silicon-on-insulator wafer, or any other semiconductor-based wafer comprising layers and structures of different materials (e.g., insulators, metals, silicides, and nitrides). Due to reduced pattern displacement, structures resulting from different lithography levels may be better aligned to each other.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

31. A lithography apparatus comprising:
a mask comprising an absorber structure arranged over a less absorbing surface, wherein the absorber structure comprises sidewalls extending in a first direction;
a first optical system configured to irradiate the mask with non-telecentric illumination having a main plane of incidence intersecting the first direction; and
a second optical system configured to guide radiation reflected off or transmitted through the mask onto a substrate;
wherein a sidewall angle of the sidewalls is at most equal to 90° minus an angle of incidence of the non-telecentric illumination and at least equal to 90° minus the sum of the angle of incidence and a half acceptance angle of the second optical system.

2. The lithography apparatus of claim 1, wherein:
the mask includes an absorber pattern comprising at least two absorber structures spaced at a feature pitch; and
the sidewall angle is at most 90° minus the sum of the angle of incidence and a first order diffraction angle resulting from the feature pitch.

3. The lithography apparatus of claim 1, wherein:
the mask includes an absorber pattern comprising at least two absorber structures spaced at a feature pitch, the absorber structures comprising leading sidewalls extending in the first direction and facing the non-telecentric illumination; and
a sidewall angle of the leading sidewalls is at least equal to 90° minus the sum of the angle of incidence and the half acceptance angle.

4. The lithography apparatus of claim 1, wherein:
the mask includes an absorber pattern comprising at least two absorber structures spaced at a feature pitch, the absorber structures comprising leading sidewalls extending in the first direction and facing the non-telecentric illumination; and
a sidewall angle of the leading sidewalls is at most equal to 90° minus the sum of the angle of incidence and a first order diffraction angle resulting from the feature pitch.

5. The lithography apparatus of claim 1, wherein:
the mask includes an absorber pattern comprising at least two absorber structures spaced at a feature pitch, the absorber structures comprising trailing sidewalls extending in the first or a second direction intersecting the main plane of incidence and facing away from the non-telecentric illumination; and
wherein a sidewall angle of the trailing sidewalls is at most equal to 90° minus the angle of incidence and at least equal to 90° minus the sum of the angle of incidence and the half acceptance angle.

6. The lithography apparatus of claim 1, wherein:
the mask includes an absorber pattern comprising at least two absorber structures spaced at a feature pitch, the absorber structures comprising trailing edges extending in the first or a second direction intersecting the main plane of incidence and facing away from the non-telecentric illumination; and
wherein a sidewall angle of the trailing edge is at least equal to 90° minus the sum of the angle of incidence and a first order diffraction angle corresponding to the feature pitch and at most equal to 90° minus the angle of incidence.

7. A mask configured to be irradiated via a non-telecentric illumination and configured to reflect or transmit the radiation in a lithography apparatus including a second optical system configured to guide the reflected or transmitted radiation onto a substrate, the mask comprising:
an absorber structure arranged over a less absorbing surface, wherein the absorber structure comprises sidewalls extending in a first direction;
wherein a sidewall angle of the sidewalls is at most equal to 90° minus an angle of incidence of the non-telecentric illumination irradiation and at least equal to 90° minus the sum of the angle of incidence and a half acceptance angle of the second optical system.

8. The mask of claim 7, further comprising:
an absorber pattern including at least two absorber structures spaced at a feature pitch; and
the sidewall angle is at most 90° minus the sum of the angle of incidence and a first order diffraction angle resulting from the feature pitch.

9. The mask of claim 7, further comprising:
an absorber pattern including at least two absorber structures spaced at a feature pitch, the absorber structures comprising leading sidewalls extending in the first direction and facing the non-telecentric illumination; and
a sidewall angle of the leading sidewalls is at least equal to 90° minus the sum of the angle of incidence and the half acceptance angle.

10. The mask of claim 7, further comprising:
an absorber pattern including at least two absorber structures spaced at a feature pitch, the absorber structures comprising leading sidewalls extending in the first direction and facing the non-telecentric illumination; and
a sidewall angle of the leading sidewalls is at most equal to 90° minus the sum of the angle of incidence and a first order diffraction angle resulting from the feature pitch.

11. The mask of claim 7, further comprising:
an absorber pattern including at least two absorber structures spaced at a feature pitch, the absorber structures comprising trailing sidewalls extending in the first or a second direction intersecting the main plane of incidence and facing away from the non-telecentric illumination; and
wherein a sidewall angle of the trailing sidewalls is at most equal to 90° minus the angle of incidence and at least equal to 90° minus the sum of the angle of incidence and the half acceptance angle.

12. The mask of claim 7, further comprising:
an absorber pattern including at least two absorber structures spaced at a feature pitch, the absorber structures comprising trailing edges extending in the first or a second direction intersecting the main plane of incidence and facing away from the non-telecentric illumination; and
wherein a sidewall angle of the trailing edge is at least equal to 90° minus the sum of the angle of incidence and a first order diffraction angle corresponding to the feature pitch and at most equal to 90° minus the angle of incidence.

13. The mask of claim 7, wherein the mask is configured as a mask for extreme ultraviolet lithography.

14. A method of fabricating integrated circuits, the method comprising:
providing a mask including an absorber structure arranged over a less absorbing surface, the absorber structure including sidewalls extending in a first direction;
introducing the mask in a lithography apparatus comprising: a first optical system configured to irradiate the mask with non-telecentric illumination having a main plane of incidence intersecting the first direction; and a second optical system configured to guide radiation reflected off or transmitted through the mask onto a semiconductor wafer arranged in an image plane of the lithography apparatus, wherein a sidewall angle of the sidewalls is at most equal to 90° minus an angle of incidence of the non-telecentric illumination and at least equal to 90° minus the sum of the angle of incidence and a half acceptance angle of the second optical system; and
illuminating the mask with non-telecentric illumination to expose a resist layer on the semiconductor wafer.

15. A method of manufacturing a mask, the method comprising:
determining, from an angle of incidence of a condenser optics of a lithography apparatus configured to irradiate a mask with non-telecentric illumination and from a feature pitch of absorber structures on a mask, an upper limit for a sidewall angle of the absorber structures that extend in a first direction intersecting a main plane of incidence of the non-telecentric illumination, wherein the upper limit is selected to facilitate symmetric behavior of plus and minus first diffraction orders; and
providing a mask with absorber structures comprising a sidewall angle not exceeding the upper limit.

16. The method of claim 15, wherein:
the mask is provided with at least two absorber structures spaced at the feature pitch; and
the absorber structures further comprise leading sidewalls extending in the first direction and facing the non-telecentric illumination, the upper limit of the sidewall angle of the leading sidewalls being equal to 90° minus the sum of the angle of incidence and the first order diffraction angle corresponding to the feature pitch.

17. The method of claim 15, wherein:
the mask is provided with at least two absorber structures spaced at the feature pitch; and
the absorber structures further comprising trailing sidewalls extending in the first or a second direction intersecting the main plane of incidence and facing away from the non-telecentric illumination, the upper limit of the sidewall angle of the trailing edge being equal to 90° minus the angle of incidence.

18. The method of claim 15, wherein providing the mask further comprises:
performing a chloride based etch process at a gas flow between about 10 to about 500 sccm, a process pressure between about 2 and about 25 mTorr, a plasma having a bias power between 20 and 300 W, and a source power between 50 and 1000 W;
wherein the respective sidewall angle of the absorber structure is adjusted by selecting an appropriate process pressure.

19. A method of manufacturing an integrated circuit, the method comprising:
providing a mask with absorber structures extending in a first direction intersecting a main plane of incidence of the non-telecentric illumination and having a sidewall angle not exceeding an upper limit, wherein the upper limit is determined from an angle of incidence of a condenser optics of a lithography apparatus configured to irradiate a mask with non-telecentric illumination and from a feature pitch of absorber structures on the mask, wherein the upper limit is selected to facilitate symmetric behavior of plus and minus first diffraction orders;
introducing the mask into the lithography apparatus; and
illuminating the mask to expose a resist layer on a semiconductor substrate arranged in an image plane of the lithography apparatus.

20. The method of claim 19, wherein:
the mask is provided with at least two absorber structures spaced at the feature pitch; and
the absorber structures further comprise leading sidewalls extending in the first direction and facing the non-telecentric illumination, the upper limit of the sidewall angle of the leading sidewalls being equal to 90° minus the sum of the angle of incidence and the first order diffraction angle corresponding to the feature pitch.

21. The method of claim 19, wherein:
the mask is provided with at least two absorber structures spaced at the feature pitch; and
the absorber structures further comprising trailing sidewalls extending in the first or a second direction intersecting the main plane of incidence and facing away from the non-telecentric illumination, the upper limit of the sidewall angle of the trailing edge being equal to 90° minus the angle of incidence.
